(19) United States
(12) Patent Application Publication
(10) Pub. No.: US 2003/0203286 A1
(43) Pub. Date: Oct. 30, 2003

(54) High-transmittance halftone phase shift mask and manufacturing method of semiconductor device

(75) Inventors: Kiyoshi Maeshima, Hyogo (JP); Naohisa Tamada, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/282,193

(22) Filed: Oct. 29, 2002

(30) Foreign Application Priority Data
Apr. 30, 2002 (JP) 2002-128381 (P)

(51) Int. Cl. G03F 1/08; G03F 7/20

(52) U.S. Cl. 430/5; 430/311

(57) ABSTRACT

The high-transmittance halftone phase shift mask is structured, in a first phase shift pattern region, with a transmission region exposing a transparent substrate and having a rectangular (square) two-dimensional shape; a phase shift region surrounding the transmissive region exposing halftone phase shift film and having a rectangular shape two-dimensional shape; and a light shielding region surrounding the phase shift region and formed of a light shielding film provided on the halftone phase shift film. With the present mask, a high-transmittance halftone phase shift mask that can transfer desired pattern clearly on the photosensitive resin and a method for producing semiconductor devices using the mask can be attained.

### BACKGROUND OF THE INVENTION

1. Field of the Invention

The present invention relates to a halftone phase shift mask, and more specifically, to the structure of a high-transmittance halftone phase shift mask used to form a small pattern in a process of manufacturing semiconductor devices, and to a manufacturing method using the mask.

2. Description of the Background Art

In the photolithography technique, implementation of higher NA (Numerical Aperture) in an exposure apparatus has been improving the resolution, and hence, making the exposure pattern smaller. On the other hand, DOF (Depth of Focus) has been degraded.

In order to improve DOF while maintaining higher resolution, a halftone phase shift mask has been employed. As shown in FIG. 8, in the cross sectional structure of the halftone phase shift mask, a halftone phase shift film 2f, with transmittance of about 1% to 6% (mainly, of 3% and 6%) and provided with a light transmitting region 4 having prescribed apertures 4h, is formed on a transparent substrate 1. In recent years, however, further improvement of DOF is required.

### SUMMARY OF THE INVENTION

The object of the present invention is to provide a high-transmittance halftone phase shift mask and a method of manufacturing semiconductor devices using the mask that is capable of transferring a desired pattern to a photosensitive resin clearly and precisely.

In the high-transmittance halftone phase shift mask according to the present invention, the phase shift region surrounds the light transmitting region and the light shielding region surrounds the phase shift region in order to expose and transfer the desired pattern, defined by the aperture of the light transmitting region, to the photosensitive resin.

According to the high-transmittance halftone phase shift mask thus structured, light transmitting through the periphery of the aperture of the light transmitting region (a diffractive light) can be shielded by the light shielding region surrounding the phase shift region. As a result, any unnecessary pattern (a dimple) not being defined by the light transmitting region is prevented from forming on the photosensitive resin, and thus desired pattern defined by the aperture of the light transmitting region can be precisely exposed and transferred on the photosensitive resin.

By introducing the high-transmittance halftone phase shift mask according to the present invention into the manufacture of semiconductor devices, the requirement for size-reduction can be met, and an unsatisfactory exposure which would result in defective semiconductor products can be avoided. Accordingly, yield in the manufacture of the semiconductor devices is improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing the structure of a high-transmittance halftone phase shift mask 100 according to the present invention;

FIG. 2 is a cross sectional view through the line II-II in FIG. 1;

FIG. 3 is a plan view showing the structure of a first phase shift pattern region 100A formed on high-transmittance halftone phase shift mask 100 according to a first embodiment of the present invention;

FIG. 4 is a plan view showing the structure of a second phase shift pattern region 100B formed on high-transmittance halftone phase shift mask 100 according to a second embodiment of the present invention;

FIG. 5 is a plan view showing the structure of a third phase shift pattern region 100C formed on high-transmittance halftone phase shift mask 100 according to a third embodiment of the present invention;

FIG. 6 is a plan view showing the structure of a fourth phase shift pattern region 100D formed on high-transmittance halftone phase shift mask 100 according to a fourth embodiment of the present invention;

FIG. 7 is a schematic illustration related to a manufacturing method of semiconductor device using a high-transmittance halftone phase shift mask 100 according to the present invention; and

FIG. 8 is a cross sectional view of the structure of a low-transmittance halftone phase shift mask according to the prior art.

### DESCRIPTION OF THE PREFERRED EMBODIMENTS

In the following, the structure of the high-transmittance halftone phase shift mask in each embodiment is described referring to the drawings.

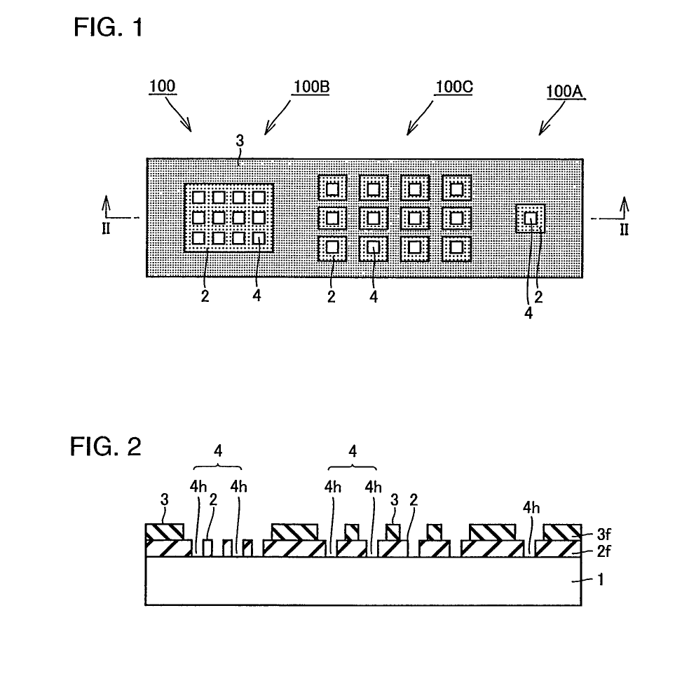

First, the structure of high-transmittance halftone phase shift mask 100 will be described with reference to FIGS. 1 and 2.

As shown in FIG. 1, high-transmittance halftone phase shift mask 100 is provided with a first phase shift pattern region 100A, a second phase shift pattern region 100B and a third phase shift pattern region 100C, on which different patterns are respectively formed. Specific structures of these first phase shift pattern region 100A, second phase shift pattern region 100B and third phase shift pattern region 100C will be described in the following first to third embodiments.

In the sectional structure of the high-transmittance halftone phase shift mask 100, halftone phase shift film 2f structured by MoSi nitride or MoSi oxided-nitride or the like and being about 70 nm to 130 nm in thickness is formed on transparent substrate 1 formed of quartz or the like. At the prescribed region of the halftone phase shift film 2f, aperture 4h exposing the surface of transparent substrate 1 is provided, which defines light transmitting region 4.

The transmittance of halftone phase shift film 2f is set at 8% or higher (40% at the highest). Additionally, halftone phase shift film 2f has its material and film thickness set such that phase difference of 180° is attained between an exposing light, which transmits transparent substrate 1 of aperture 4h, and another exposing light, which transmits halftone phase shift film 2f and transparent substrate 1.

On halftone phase shift film 2f, a light shielding film 3f structured by Cr or the like and having a thickness of about 50 nm to 110 nm for shielding exposing light is formed, which defines light shielding region 3.

In embodiments of the present invention, as an exposing apparatus using high-transmittance halftone phase shift mask 100, an excimer laser exposing apparatus having one-fourth reduction function and employing exposing lights KrF (wavelength 248 nm) and ArF (wavelength 193 nm) is used.

In the following description of each embodiment, dimension indicates values as being transferred on the photosensitive resin applied on the semiconductor wafer, and additionally, dimension as on the photomask is given as a reference. Note that when the excimer laser exposing apparatus having one-fourth reduction function is used, the value will be magnified by a factor of four.

(First Embodiment)

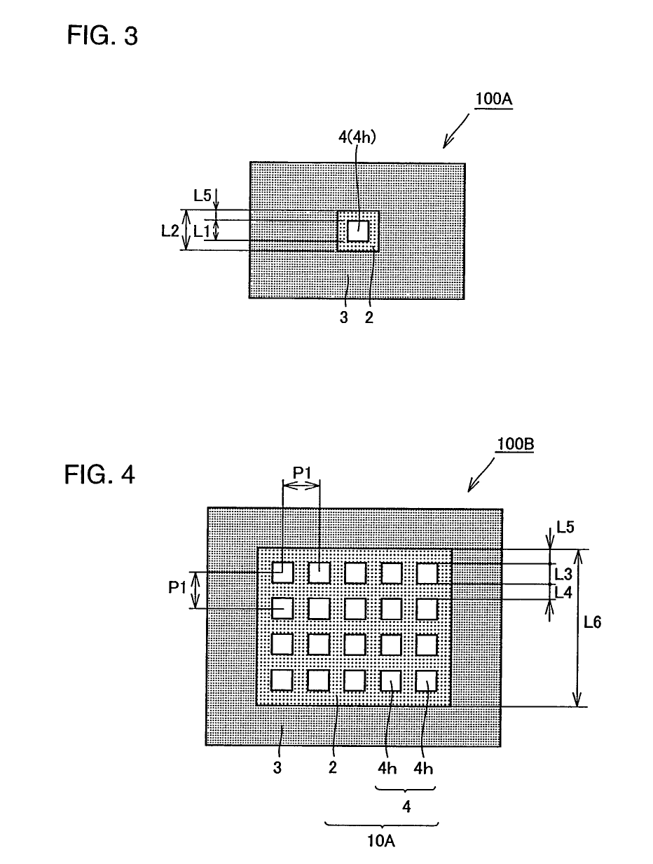

Referring to FIG. 3, the structure of first phase shift pattern region 100A formed on high-transmittance halftone phase shift mask 100 according to a first embodiment will be described.

The first phase shift pattern region 100A is an independent pattern (distanced from adjacent aperture by at least 0.5 μm (at least 2.0 μm on the mask)) and includes: transmitting region 4 as an aperture 4h exposing transparent substrate 1 and having a rectangular (square) two-dimensional shape; phase shift region 2 consisted of a region surrounding transmitting region 4 and exposing halftone phase shift film 2f and having a rectangular two-dimensional shape; and light shielding region 3 surrounding phase shift region 2 on halftone phase shift film 2f.

The aperture dimension (L1) of aperture 4h is at most 0.20 μm (at most 0.8 μm on the mask); the aperture dimension of the region exposing halftone phase shift film 2f (L2) is at most 0.40 μm (at most 1.60 μm on the mask); and the halftone length (L5) is at most 0.20 μm (at most 0.8 μm on the mask).

(Function and Effects)

When first phase shift pattern region 100A in high-transmittance halftone phase shift mask 100 is not provided with light shielding region 3, the amount of exposing light transmitting phase shift region 2 will be larger than that of conventional low-transmittance halftone phase shift mask, and hence (flare-like) dimple will be undesirably formed due to the exposure of the photosensitive resin by the nth diffractive light (particularly, the first diffractive light) of the exposing light. Thus, in the present embodiment, aperture 4h is completely surrounded by light shielding region 3 to shield exposing light in the unnecessary portion, while maintaining the function as a halftone phase shift mask. Accordingly, dimple formation due to the exposure of the photosensitive resin is prevented.

As a result, when high-transmittance halftone phase shift mask 100 according to the present invention is introduced into the manufacture of semiconductor devices, the requirement for size-reduction can be met and an unsatisfactory exposure which would result in defective semiconductor products can be avoided. Accordingly, yield in the manufacture of the semiconductor devices is improved.

In regard of the distance from an edge of aperture 4h to light shielding region 3 (L5=(L2−L1)/2: hereinafter referred to as halftone length), the longer the halftone length (L5), the more light intensity of aperture 4h increases. On the other hand, the light intensity of the region where dimple would be formed will increases as well. Though shorter halftone length will suppress the light intensity of the region where dimple would be formed, the light intensity at aperture 4h decreases as well. Accordingly, suitable halftone length (L5) should be determined considering the light intensity of aperture 4h and that of the region where dimple would be formed.

(Second Embodiment)

Referring to FIG. 4, the structure of second phase shift pattern region 100B formed on high-transmittance halftone phase shift mask 100 according to a second embodiment will be described.

The second phase shift pattern region 100B includes a pattern region 10A to which apertures 4h exposing transparent substrate 1 are densely gathered. More specifically, pattern region 10A is formed so as to be surrounded by light shielding region 3. Pattern region 10A consists of light transmitting region 4 having a plurality of apertures 4h arranged to be densely gathered in a matrix (in directions of rows and columns) and phase shift region 2 surrounding each aperture 4h. No light shielding region 3 is formed in pattern region 10A.

A pitch (P1) of aperture 4h is at most 0.32 μm (at most 1.28 μm on the mask); opening dimension L3) of aperture 4h is at most 0.25 μm (at most 1.00 μm on the mask); dimension between apertures (L4) is at most 0.14 μm (at most 0.56 μm on the mask); and halftone length (L5) is at most 0.20 μm (at most 0.80 μm on the mask). There is no limitation on the dimension (L6) of light transmitting region 4.

(Function and Effects)

According to the second phase shift pattern region 100B in high-transmittance halftone phase shift mask 100, in light transmitting region 4, exposing lights transmitting through adjacent apertures 4h and nth diffractive light of the exposing light will not generate light intensity that would incur dimple formation due to interference effect. In the periphery of dimple formation will be suppressed by light transmitting region 3. Hence, in the present embodiment also, formation of dimple is prevented by shielding exposing light in the unnecessary region while maintaining the function of the halftone phase shift mask, which would otherwise be resulted from the exposure of the photosensitive resin.

As a result, when high-transmittance halftone phase shift mask 100 according to the present invention is introduced into the manufacture of semiconductor devices, the requirement for size-reduction can be met and an unsatisfactory exposure which would result in defective semiconductor products can be avoided. Accordingly, yield in the manufacture of the semiconductor devices is improved.

Halftone length (L5) should be determined appropriately, as in the first embodiment, taking into consideration of light intensity of aperture 4h and that of the region where dimple may be formed so that desired hole pattern corresponding to aperture 4h can be attained on the photosensitive resin.

(Third Embodiment)

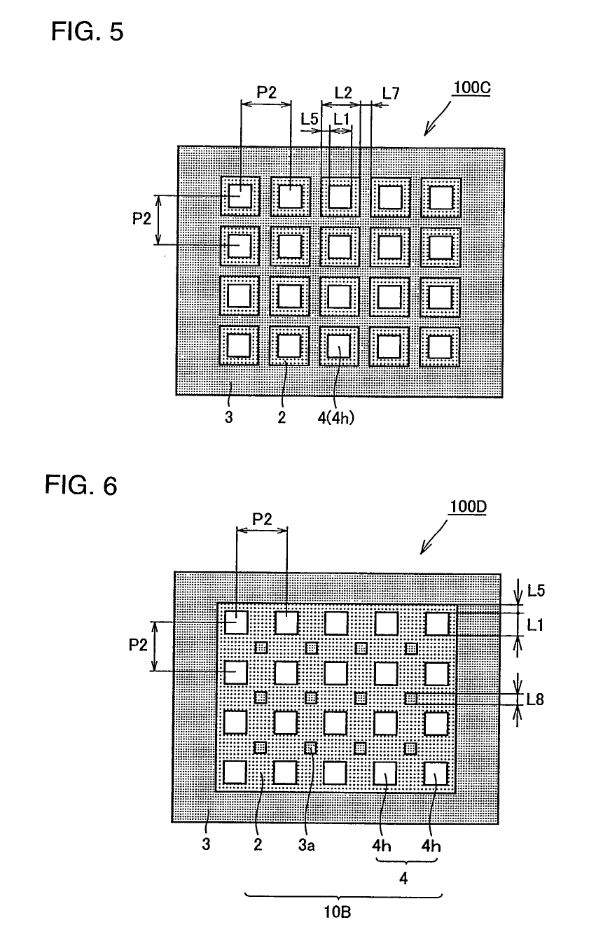

Referring to FIG. 5, the structure of third phase shift pattern region 100C formed on high-transmittance halftone phase shift mask 100 according to a third embodiment will be described.

In third phase shift pattern region 100C, a plurality of apertures 4h exposing transparent substrate 1 are arranged in an intermediate pitch between that of the first embodiment and that of the second embodiment. More specifically, third phase shift pattern region 100C includes light transmitting region 4 having a plurality of apertures 4h arranged in a matrix (arranged in directions of row and column), a phase shift region being provided surrounding each aperture 4h, and light shielding region 3 surrounding each phase shift region 2.

A pitch (P2) of aperture 4h is at least 0.32 μm and at most 0.50 μm (at least 1.28 μm and at most 2.0 μm on the mask); opening dimension (L1) of aperture 4h is at most 0.25 μm (at most 1.00 μm on the mask); dimension between apertures (L7) is at most 0.30 μm (at most 1.20 μm on the mask); and halftone length (L5) is at most 0.20 μm (at most 0.80 μm on the mask).

(Function and Effects)

According to third phase shift pattern region 100C in high-transmittance halftone phase shift mask 100, as in the first embodiment, aperture 4h is completely surrounded by light shielding region 3. Hence, in the present embodiment also, formation of dimple is prevented by shielding exposing light in the unnecessary region while maintaining the function of the halftone phase shift mask, which would otherwise be resulted from the exposure of photosensitive resin.

As a result, when high-transmittance halftone phase shift mask 100 according to the present invention is introduced into the manufacture of semiconductor devices, the requirement for size-reduction can be met and an unsatisfactory exposure which would result in defective semiconductor products can be avoided. Accordingly, yield in the manufacture of the semiconductor devices is improved.

Halftone length (L5) should be determined appropriately, as in the first embodiment, taking into consideration of light intensity of aperture 4h and that of the region where dimple may be formed so that desired hole pattern corresponding to aperture 4h can be attained on the photosensitive resin.

(Fourth Embodiment)

Referring to FIG. 6, the structure of fourth phase shift pattern region 100D according to a fourth embodiment will be described.

Fourth phase shift pattern region 100D is different from third phase shift pattern region 100C in that an auxiliary light transmitting region 3a is provided in the region where dimple may be formed.

Specifically, fourth phase shift pattern region 100D has a pattern region 10B surrounded by light shielding region 3. Pattern region 10B includes light transmitting region 4 having a plurality of apertures 4h arranged in a matrix (in directions of row and column) and phase shift aperture 4h, as in the first embodiment, light intensity that would incur region 2 surrounding each aperture 4h.

On halftone phase shift film 2f, auxiliary light transmitting region 3a is provided in the region where dimple may formed, which corresponds to the region where diffractive lights of exposing lights transmitted through adjacent apertures 4h overlap with each other on the photosensitive surface. Auxiliary light transmitting region 3a may be provided at the intersection of diagonal lines of each aperture extended therefrom, for example.

A pitch (P2) of aperture 4h is at least 0.32 μm and at most 0.50 μm (at least 1.28 μm and at most 2.0 μm on the mask); opening dimension (L1) of aperture 4h is at most 0.25 μm (at most 1.00 μm on the mask); halftone length (L5) is at most 0.20 μm (at most 0.80 μm on the mask); and side length (L8) of auxiliary light shielding region 3a is at most 0.30 μm (at most 1.20 μm on the mask).

(Function and Effects)

According to fourth phase shift pattern region 100D in high-transmittance halftone phase shift mask 100, by providing auxiliary light shielding region 3a only at the region where dimple may be formed due to the exposure of the photosensitive resin, formation of the dimple can be prevented which would otherwise be resulted from the exposure of the photosensitive resin.

In the periphery of aperture 4h, as in the first embodiment, light intensity that would incur dimple formation will be suppressed by light transmitting region 3. Hence, in the present embodiment also, formation of dimple is prevented by shielding exposing light in the unnecessary region while maintaining the function of the halftone phase shift mask, which would otherwise be resulted from the exposure of the photosensitive resin.

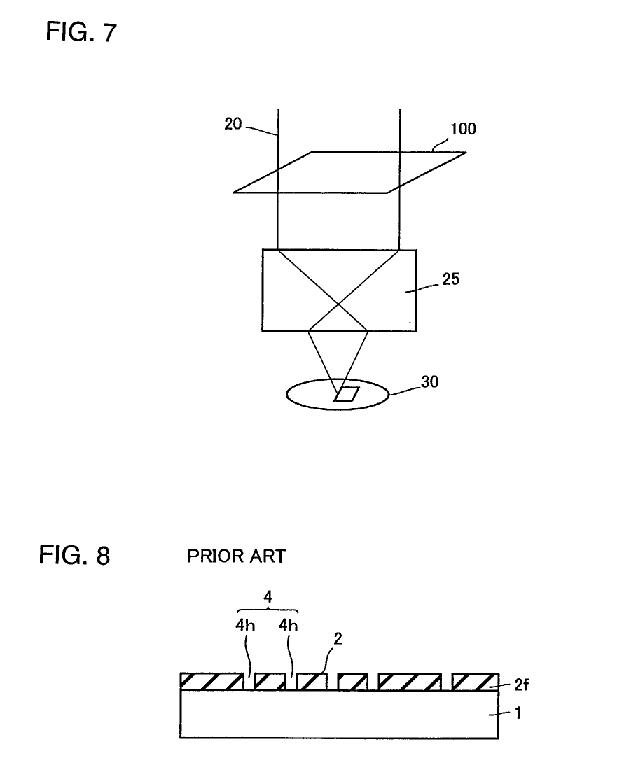

When semiconductor devices are manufactured using high-transmittance halftone phase shift mask 100 of the present invention, as shown in FIG. 7, exposing light 20 is directed to high-transmittance halftone phase shift mask 100, then exposing light 20 transmitted therethrough is utilized for reduction exposure by an exposure apparatus 25, which includes optical lenses and the like. Thus, transfer pattern is exposed on a semiconductor wafer 30.

As a result, the manufacture of semiconductor devices which meets the requirement for size-reduction can be attained and an unsatisfactory exposure which would result in defective semiconductor products can be avoided. Accordingly, yield in the manufacture of the semiconductor devices is improved.

Halftone length (L5) should be determined appropriately, as in the first embodiment, taking into consideration of light intensity of aperture 4h and that of the region where dimple may be formed so that desired hole pattern corresponding to aperture 4h can be attained on the photosensitive resin.

According to the high-transmittance halftone phase shift mask of the present invention, any unnecessary pattern (a dimple) not being defined by the light transmitting region is prevented from forming on the photosensitive resin, and thus desired pattern defined by the aperture of the light transmitting region can be precisely exposed and transferred on the photosensitive resin. As a result, the manufacture of semiconductor devices which meets the requirement for size-reduction can be attained and an unsatisfactory exposure which would result in defective semiconductor products can be avoided. Accordingly, yield in the manufacture of the semiconductor devices is improved.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A high-transmittance halftone phase shift mask used for exposing a prescribed pattern on a photosensitive resin, comprising:
a light transmitting region having an aperture exposing a transparent substrate;
a phase shift region provided on said transparent substrate and exposing a halftone phase shift film having light transmittance of at least 8%; and
a light shielding region formed by a light shielding film provided on said halftone phase shift film; wherein
said phase shift region is provided so as to surround said light transmitting region, and said light shielding region is provided so as to surround said phase shift region to expose and transfer desired pattern defined by said aperture of said light transmitting region on said photosensitive resin.

2. The high-transmittance halftone phase shift mask according to claim 1, further comprising:
a pattern region surrounded by said light shielding region; wherein
said pattern region consists of said light transmitting region including a plurality of said apertures arranged in a prescribed pitch to be densely gathered, and said phase shift region surrounding each of said apertures.

3. The high-transmittance halftone phase shift mask according to claim 2, wherein
said apertures are arranged in a matrix; and
a pitch of the arrangement of said apertures is at most 0.32 μm as transferred on said photosensitive resin.

4. The high-transmittance halftone phase shift mask according to claim 1, wherein
said light transmitting region has a plurality of said apertures arranged in a prescribed pitch;
said phase shift region is provided so as to surround each of said apertures; and
said light shielding region is provided so as to surround each of said phase shift regions.

5. The high-transmittance halftone phase shift mask according to claim 4, wherein
said apertures are arranged in a matrix; and
a pitch of the arrangement of said apertures is at least 0.32 μm and at most 0.50 μm as transferred on said photosensitive resin.

6. The high-transmittance halftone phase shift mask according to claim 1, further comprising:
a pattern region surrounded by said light shielding region; wherein
said pattern region includes
said light transmitting region having a plurality of said apertures arranged in a prescribed pitch,
said phase shift region provided so as to surround each of said apertures, and
an auxiliary light shielding region provided on a position on the halftone phase shift film constituting said phase shift region, at which diffractive lights of exposing lights transmitted through said adjacent apertures overlap with each other on said photosensitive resin.

7. The high-transmittance halftone phase shift mask according to claim 6, wherein
said apertures are arranged in a matrix and is rectangular in shape;
a pitch of said apertures is at least 0.32 μm and at most 0.50 μm as transferred on said photosensitive resin;
said auxiliary light shielding region is provided at a region where diagonal lines of apertures extended therefrom intersect with each other.

8. A method for manufacturing semiconductor devices using a high-transmission halftone phase shift mask for exposing a prescribed pattern on a photosensitive resin, wherein
the mask includes
a light transmitting region having an aperture exposing a transparent substrate,
a phase shift region provided on said transparent substrate and exposing a halftone phase shift film having light transmittance of at least 8%, and
a light shielding region formed by a light shielding film provided on said halftone phase shift film; and wherein
said phase shift region is provided so as to surround said light transmitting region, and said light shielding region is provided so as to surround said phase shift region to expose and transfer desired pattern defined by said aperture of said light transmitting region on said photosensitive resin.
